(19) United States
(12) Patent Application Publication
(10) Pub. No.: US 2019/0148119 A1
(43) Pub. Date: May 16, 2019

(54) PLASMA PROCESSING APPARATUS

(71) Applicant: SAMSUNG ELECTRONICS CO., LTD., Suwon-si (KR)

(72) Inventors: Jung-mo SUNG, Seoul (KR); Sang-rok OH, Yongin-si (KR); Eun-woo LEE, Seongnam-si (KR); Kwang-nam KIM, Suwon-si (KR); Jong-woo SUN, Hwaseong-si (KR); Jung-pyo HONG, Seoul (KR)

(21) Appl. No.: 16/021,120

(22) Filed: Jun. 28, 2018

(30) Foreign Application Priority Data
Nov. 15, 2017 (KR) 10-2017-0152501

(51) Int. Cl. H01J 37/32; H01L 21/683

(52) U.S. Cl. CPC H01J 37/32724; H01J 37/3211; H01L 21/6833; H01J 2237/327; H01J 37/32449; H01J 2237/0266; H01J 2237/032; H01J 37/32119

(57) ABSTRACT

Provided is a plasma processing apparatus for controlling a distribution of plasma at an edge region of a chamber during a plasma process, thereby reliably performing the plasma process on a semiconductor substrate. The plasma processing apparatus includes a chamber including an outer wall defining a reaction space and a window covering an upper portion of the outer wall; a coil antenna positioned above the window and including at least two coils; and an electrostatic chuck (ESC) positioned in a lower portion of the chamber, wherein an electrode is located inside the ESC, wherein the electrode includes a first electrode for chucking and at least one second electrode, the at least one second electrode provided at an edge of the inside of the ESC so as to have a tilt with respect to the top surface of the ESC.

### CROSS-REFERENCE TO RELATED APPLICATION

Korean Patent Application No. 10-2017-0152501, filed on Nov. 15, 2017, in the Korean Intellectual Property Office, and entitled: “Plasma Processing Apparatus,” is incorporated by reference herein in its entirety.

### BACKGROUND

### 1. Field

Embodiments relate to a plasma processing apparatus.

### 2. Description of the Related Art

Plasma is widely used in manufacturing processes of semiconductor devices, plasma display panels (PDPs), liquid crystal displays (LCDs), solar cells, etc. Representative plasma processes may include dry etching, plasma-enhanced chemical vapor deposition (PECVD), sputtering, and aching.

### SUMMARY

The embodiments may be realized by providing an apparatus for plasma processing an object, the apparatus including a chamber that includes an outer wall and a window, the outer wall defining a reaction space in which plasma is formed, and the window covering an upper portion of the outer wall; a coil antenna positioned above the window, the coil antenna including at least two coils; and an electrostatic chuck (ESC) positioned in a lower portion of the chamber, wherein the object to be processed is supportable on a top surface of the ESC and an electrode is located inside the ESC, the electrode includes a first electrode for holding the object and at least one second electrode, the first electrode provided in an internal central portion of the ESC so as to be parallel with the top surface of the ESC, and the at least one second electrode provided at an edge of the inside of the ESC so as to have a tilt with respect to the top surface of the ESC.

The embodiments may be realized by providing an apparatus for plasma processing an object, the apparatus including a chamber that includes an outer wall and a window, the outer wall defining a reaction space in which plasma is formed, and the window covering an upper portion of the outer wall; a coil antenna positioned above the window, the coil antenna including at least two coils; an electrostatic chuck (ESC) positioned in a lower portion of the chamber; and an ESC support configured to support the ESC, wherein the object to be processed is supportable on a top surface of the ESC and an electrode is located inside the ESC; and a dielectric insertion layer is formed inside the ESC support, and a high-k dielectric in a solid state or a fluid state is provided in the dielectric insertion layer to be moveable or to be adjustable in level.

The embodiments may be realized by providing an apparatus for plasma processing an object, the apparatus including a chamber that includes an outer wall and a window, the outer wall defining a reaction space in which plasma is formed, and the window covering an upper portion of the outer wall; a coil antenna positioned above the window, the coil antenna including an inner coil, an outer coil, and an additional coil; and an electrostatic chuck (ESC) positioned in a lower portion of the chamber, wherein the object to be processed is supportable on a top surface of the ESC and an electrode is located inside the ESC, the window includes a groove at an edge of a top surface thereof, the additional coil being in the groove.

### BRIEF DESCRIPTION OF THE DRAWINGS

Features will be apparent to those of skill in the art by describing in detail exemplary embodiments with reference to the attached drawings in which:

FIG. 1 illustrates a schematic diagram of a plasma processing apparatus according to an embodiment;

FIGS. 2A through 2C illustrate cross-sectional views of electrostatic chuck (ESC) structures respectively applicable to plasma processing apparatuses, according to embodiments;

FIGS. 3A through 3C illustrate conceptual diagrams showing a comparison of the effect of a plasma processing apparatus using the ESC structure illustrated in FIG. 2A with the effect of a plasma processing apparatus using an ESC not having a tilting electrode therewithin;

FIGS. 4A and 4B illustrate graphs showing effects obtained when a radio frequency (RF) pulse voltage and a direct current (DC) pulse voltage are respectively applied to a tilting electrode in the plasma processing apparatus illustrated in FIG. 2A;

FIGS. 5A through 5D illustrate cross-sectional views and plan views of an ESC support structure applicable to a plasma processing apparatus, according to an embodiment;

FIGS. 6A and 6B illustrate conceptual diagrams of the effects of a plasma processing apparatus using the ESC support structure illustrated in FIGS. 5A and 5C;

FIGS. 7A through 7D illustrate cross-sectional views and plan views of an ESC support structure applicable to a plasma processing apparatus, according to another embodiment;

FIGS. 8A and 8B illustrate cross-sectional views of an ESC support structure applicable to plasma processing apparatuses, respectively, according to an embodiment;

FIGS. 9A and 9B illustrate cross-sectional views of a window structure applicable to a plasma processing apparatus, according to an embodiment;

FIG. 10 illustrates a flowchart of a method of controlling the distribution of plasma, according to an embodiment; and

FIG. 11 illustrates a flowchart of a procedure for manufacturing a semiconductor device using the method illustrated in FIG. 10, according to an embodiment.

### DETAILED DESCRIPTION

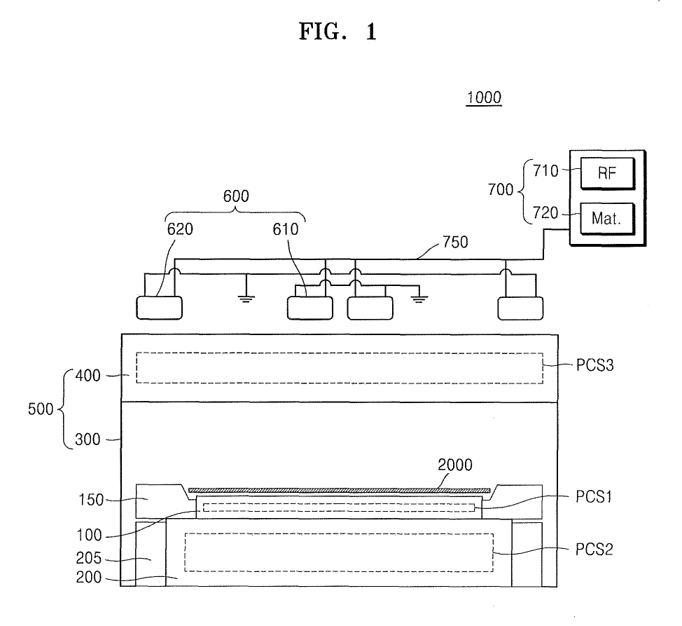

FIG. 1 illustrates a schematic diagram of a plasma processing apparatus according to an embodiment.

Referring to FIG. 1, a plasma processing apparatus 1000 may include an electrostatic chuck (ESC) 100, an ESC support 200, a chamber 500, a coil antenna 600, and a radio frequency (RF) power supply 700.

The ESC 100 may be positioned in a lower portion of the chamber 500 (e.g., as shown in FIG. 1). An object to undergo a plasma process, e.g., a wafer 2000, may be placed and fixed to the top surface of the ESC 100. The ESC 100 may fix or hold the wafer 2000 using an electrostatic force. The ESC 100 may include an electrode therewithin to chuck and dechuck (e.g., hold and release) the wafer 2000 and may be supplied with power from a power source. In an implementation, other control systems for loading the wafer 2000 on the ESC 100 and unloading the wafer 2000 from the ESC 100 may also be provided inside and outside the chamber 500.

An edge ring 150 may be provided around the ESC 100 to surround the wafer 2000. The edge ring 150 may be formed of silicon. The edge ring 150 may have an effect of expanding a silicon region of the wafer 2000, thereby reducing or preventing plasma from being concentrated on the edge of the wafer 2000. The edge ring 150 may be a single-ring type or a dual-ring type. The single-ring type may be called a focus ring and the dual-ring type may be called a combo ring.

The edge ring 150 may also be etched together with the wafer 2000 during a plasma process, and a change may occur over time. For example, the change occurring over time may be a nonuniform distribution of an electric field (E-field) and/or plasma at an edge region inside the chamber 500, and the nonuniform distribution could occur due to performance deterioration caused by etching of the edge ring 150. Here, the edge region inside the chamber 500 may correspond to an edge of the wafer 2000. The nonuniform distribution of plasma could cause an error in a plasma process for the wafer 2000 and eventually a failure of semiconductor devices manufactured from the wafer 2000.

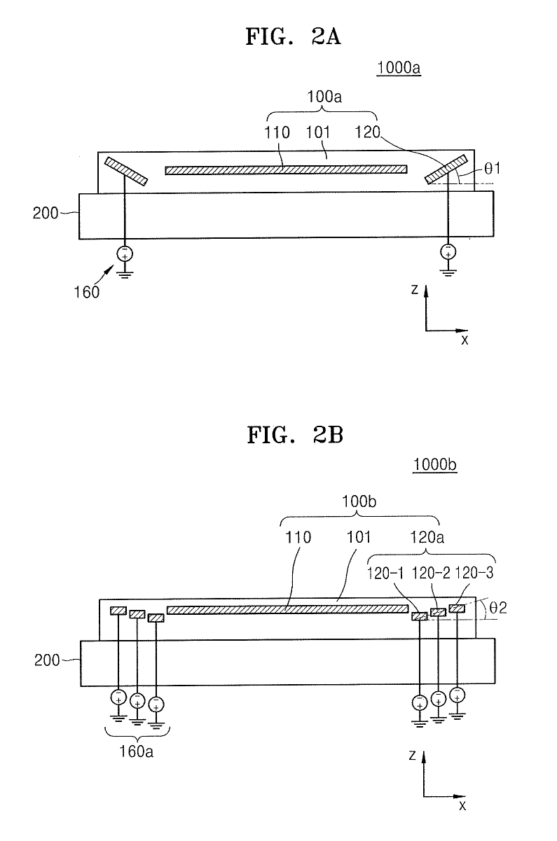

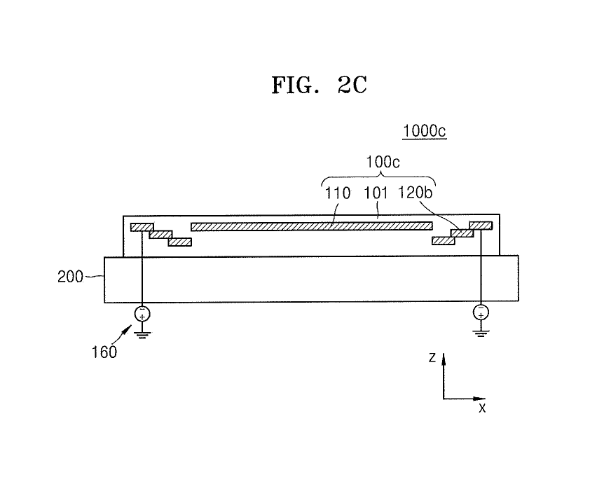

The plasma processing apparatus 1000 may use the ESC 100 including a first plasma distribution control structure PCS1 (which may help prevent a nonuniform plasma distribution by controlling the density of an E-field and/or plasma in the edge region inside the chamber 500). When the ESC 100 includes the first plasma distribution control structure PCS1, a change occurring over time due to etching of the edge ring 150 may be prevented. For example, the first plasma distribution control structure PCS1 may be or may include a tilting electrode positioned inside the ESC 100. The first plasma distribution control structure PCS1 will be described in detail with reference to FIGS. 2A through 4B below.

In an implementation, the ESC support 200 may support the ESC 100 positioned thereon and may be formed of, e.g., a metal such as aluminum. In an implementation, the ESC support 200 may be formed of a ceramic insulator such as alumina. When the ESC support 200 is formed of a metal, heat transfer to the ESC 100 or the wafer 2000 or heat release from the ESC 100 or the wafer 2000 may be increased. For example, a heating element (e.g., a heater) may be provided inside the ESC support 200 and heat from the heater may be readily transferred to the ESC 100 or the wafer 2000. An insulator 205 may be provided to surround an outer circumference of the ESC support 200. A power-applying electrode may be provided under a center of the ESC support 200 to apply power to an electrode inside the ESC 100.

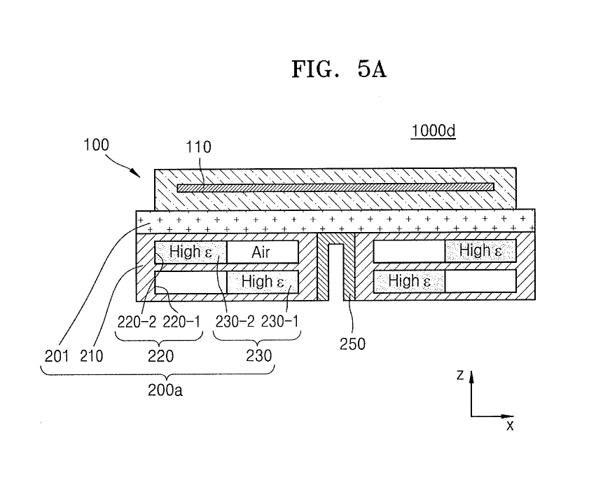

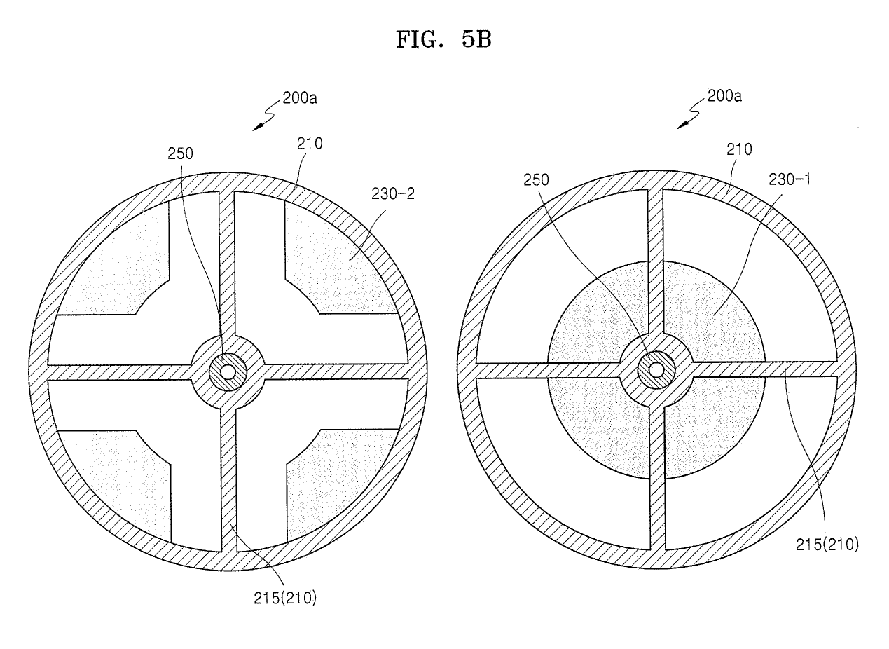

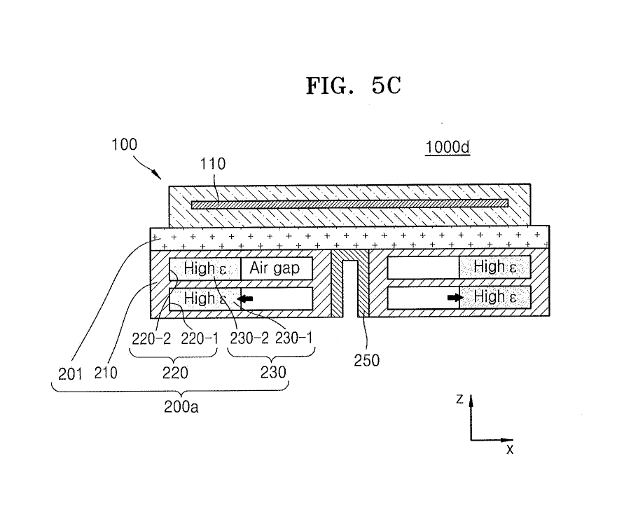

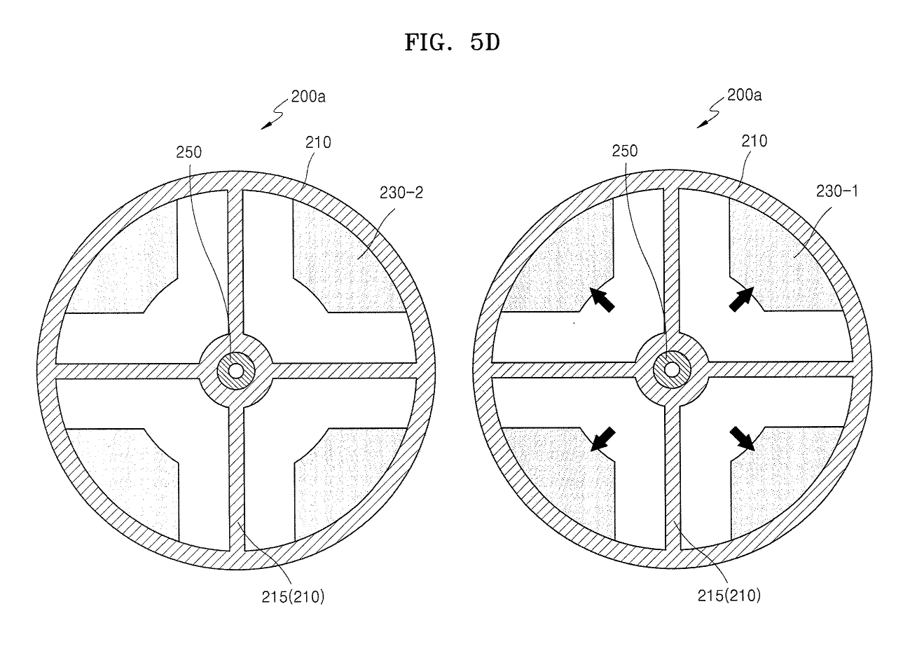

The plasma processing apparatus 1000 may use the ESC support 200 including a second plasma distribution control structure PCS2 (which may help reduce or prevent a nonuniform plasma distribution at an edge region). When the ESC support 200 includes the second plasma distribution control structure PCS2, a change occurring over time due to etching of the edge ring 150 may be prevented. For example, the second plasma distribution control structure PCS2 may include a dielectric insertion layer inside the ESC support 200 and a high-k dielectric inside the dielectric insertion layer. The second plasma distribution control structure PCS2 will be described in detail with reference to FIGS. 5A through 8B below.

The chamber 500 may include an outer wall 300 and a window 400.

The outer wall 300 may define a reaction space in which plasma is formed and may seal the reaction space from the outside air or environment. The outer wall 300 may be formed of a metallic material and may maintain a ground state to block noise from outside the chamber 500 during a plasma process. An insulating liner may be provided at an inside of the outer wall 300. The insulating liner may help protect the outer wall 300 and cover metallic structures protruding from the outer wall 300, thereby preventing arcing or the like from occurring inside the chamber 500. The insulating liner may be formed of ceramic or quartz.

In an implementation, at least one viewport may be formed at the outer wall 300, and the inside of the chamber 500 may be monitored through the viewport. For example, a probe or an optical emission spectroscopy (OES) device may be coupled to the viewport and electrically connected to an analyzer. The analyzer may analyze a plasma state such as the density or uniformity of plasma inside the chamber 500 using an analysis program, based on plasma data received from the probe or the OES device.

In an implementation, the window 400 may have a circular plate shape covering an upper portion of the outer wall 300 (e.g., an open end of the reaction space formed by the outer wall 300). In an implementation, the shape of the window 400 may vary with the structure of a chamber including the window 400. In an implementation, the window 400 may have an elliptic plate shape or a polygonal plate shape or a convex dome shape. When the window 400 has a dome shape, a horizontal cross section of the window 400 may be a circular ring, an elliptic ring, or a polygonal ring.

The window 400 may be formed of a dielectric material having relatively lower permittivity. For example, the window 400 may be formed of alumina (Al₂O₃), quartz, silicon carbide (SiC), silicon oxide (SiO₂), Teflon, G10 epoxy, or other dielectric, nonconductive or semiconductive material. In an implementation, the window 400 may be formed of alumina or quartz. When the window 400 is formed of alumina, the window 400 may have a thickness of about 20 mm. When the window 400 is formed of quartz, the window 400 may have a thickness of about 30 mm. The diameter of the window 400 may be about 400 mm to about 500 mm. In an implementation, the material and the size of the window 400 may vary with the function or structure of a chamber including the window 400.

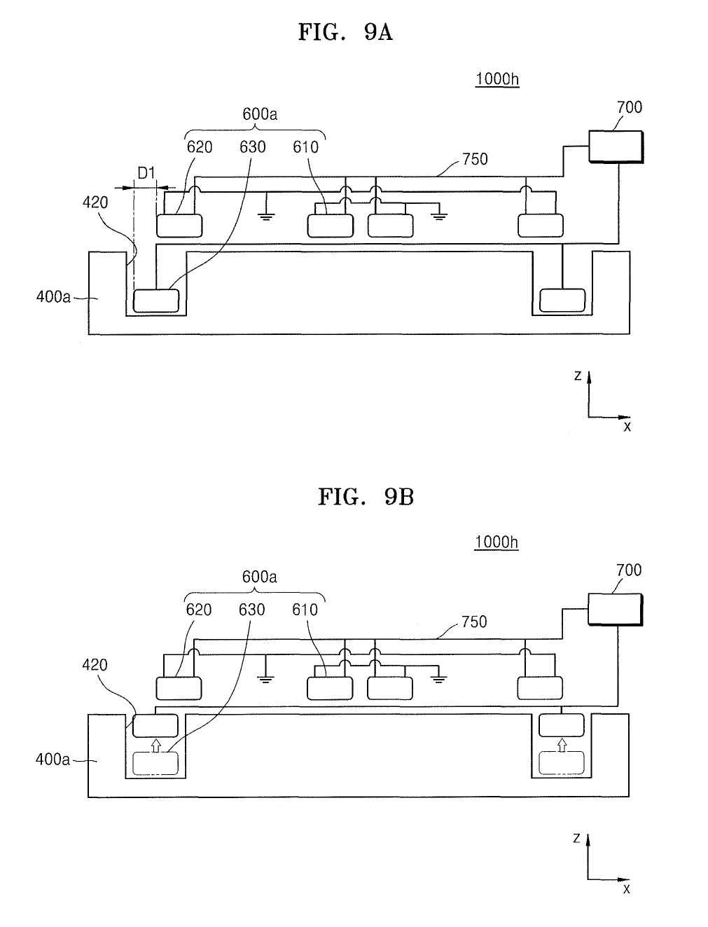

In the plasma processing apparatus 1000, the window 400 may include a third plasma distribution control structure PCS3 (which may help reduce or prevent a nonuniform plasma distribution at an edge region). When the window 400 includes the third plasma distribution control structure PCS3, a change occurring over time due to etching of the edge ring 150 may be prevented. In an implementation, the third plasma distribution control structure PCS3 may include a coil insertion groove at an edge of the top surface of the window 400, and an additional coil provided at the coil insertion groove. The third plasma distribution control structure PCS3 will be described in detail with reference to FIGS. 9A and 9B below.

Process gases may be supplied to the chamber 500 through a supply pipe and a gas ejection head. The term “process gases” may refer to all gases including a source gas, a reactant gas, and a purge gas that are used for a plasma process. A pump may be coupled to the chamber 500 through an exhaust pipe. The pump may discharge gas by-products, which have been produced inside the chamber 500, through vacuum pumping. The pump may also control the inner pressure of the chamber 500. Although the ESC 100 and the ESC support 200 are described as separate elements from the chamber 500 in the current embodiment, in an implementation, the ESC 100 and the ESC support 200 may be considered as being included in the chamber 500.

The coil antenna 600 may include an inner coil 610 and an outer coil 620. The coil antenna 600 may be positioned above the window 400 (e.g., outside of the chamber 500), as shown in FIG. 1. For example, the inner coil 610 may be positioned above a central portion of the window 400, and the outer coil 620 may be positioned above an edge portion of the window 400. The outer coil 620 may surround the inner coil 610 and may be spaced therefrom.

The inner coil 610 and the outer coil 620 may be connected to the RF power supply 700 through a wiring circuit 750. For example, the outer coil 620 may be connected to the wiring circuit 750 through an inner connecting terminal and an outer connecting terminal. The inner connecting terminal of the outer coil 620 may be connected to a matcher 720 and an RF generator 710 through a variable capacitor or the like of the wiring circuit 750. The outer connecting terminals of the outer coil 620 may be connected to a capacitor connected to a ground. The inner coil 610 may be connected to the RF power supply 700 through an inner connecting terminal and an outer connecting terminal. The inner connecting terminal of the inner coil 610 may be connected to the RF power supply 700 through a variable capacitor and an inductor. The outer connecting terminals of the inner coil 610 may be connected to the ground.

The structure of the coil antenna 600 and the connection between the coil antenna 600 and the RF power supply 700 through the wiring circuit 750, which have been described above, may be just an example. In an implementation, the structure of the coil antenna 600 and the connection between the coil antenna 600 and the RF power supply 700 through the wiring circuit 750 may vary with a plasma process.

When a coil insertion groove is formed in the window 400, the coil antenna 600 may also include the additional coil, which is provided at the coil insertion groove as an element of the third plasma distribution control structure PCS3. The additional coil will be described in detail with reference to FIGS. 9A and 9B below.

The RF power supply 700 may tune power that is provided to the inner coil 610 and the outer coil 620, through dynamic tuning of variable capacitors. In an implementation, the coil antenna 600 and the wiring circuit 750 may be tuned to supply more power to one of the inner coil 610 and the outer coil 620 than to the other or to uniformly supply power to the inner coil 610 and the outer coil 620. In an implementation, current may be tuned to flow in the inner coil 610 and the outer coil 620 at a predetermined ratio using variable capacitors.

The RF power supply 700 may include the RF generator 710 and the matcher 720. The RF generator 710 may generate RF power and the matcher 720 may control impedance, thereby stabilizing plasma. At least two RF generators 710 may be provided. When a plurality of RF generators 710 are provided, different frequencies may be used to realize various tuning characteristics. The matcher 720 may be connected to the coil antenna 600 through the wiring circuit 750. The matcher 720 may be considered as being included in the wiring circuit 750.

In an implementation, a lower RF power supply may be provided to supply RF power to a power-applying electrode of the ESC 100. The lower RF power supply may also include an RF generator and a matcher and may supply RF power to the wafer 2000 through the power-applying electrode. The lower RF power supply may also include a plurality of RF generators, and different frequencies may be used to realize various tuning characteristics.

The plasma processing apparatus 1000 may include the ESC 100 including the first plasma distribution control structure PCS1, the ESC support 200 including the second plasma distribution control structure PCS2, and/or a group of the window 400 and the coil antenna 600, which includes the third plasma distribution control structure PCS3. For example, the plasma processing apparatus 1000 may include all of the three elements described above, i.e., the ESC 100 including the first plasma distribution control structure PCS1, the ESC support 200 including the second plasma distribution control structure PCS2, and the group of the window 400 and the coil antenna 600, which includes the third plasma distribution control structure PCS3, only one of the three elements described above, or only two of the three elements described above.

When the plasma processing apparatus 1000 includes the ESC 100, the ESC support 200, and/or the group of the window 400 and the coil antenna 600, of which each includes a plasma distribution control structure, the plasma processing apparatus 1000 may control the density of an E-field and/or plasma at an edge region, thereby preventing a nonuniform plasma distribution in the edge region. Due to the improved plasma distribution in the edge region, the plasma processing apparatus 1000 may perform a stable plasma process. As a result, the plasma processing apparatus 1000 may produce excellent and reliable semiconductor devices based on the stable plasma process. In addition, the first plasma distribution control structure PCS1 of the ESC 100, the second plasma distribution control structure PCS2 of the ESC support 200, and the third plasma distribution control structure PCS3 of the group of the window 400 and the coil antenna 600 may be isolated from the inside of the chamber 500, in which plasma is generated, and the first through third plasma distribution control structures PCS1 through PCS3 may not be damaged, contaminated, or transformed by the plasma inside the chamber 500 and may not have a physical influence on a flow of plasma inside the chamber 500.

FIGS. 2A through 2C illustrate cross-sectional views of ESC structures respectively applicable to plasma processing apparatuses, according to embodiments. Redundant descriptions that have been made with reference to FIG. 1 may be briefly stated or omitted.

Referring to FIG. 2A, in a plasma processing apparatus 1000a, an ESC 100a may include a body 101, a central electrode 110, and a first tilting electrode 120. The body 101 may form the exterior of the ESC 100a and may be substantially the same as the ESC 100a. However, the ESC 100a includes interior electrodes, e.g., the central electrode 110 and the first tilting electrode 120, while the body 101 may refer to a portion excluding the electrodes 110 and 120. In an implementation, the body 101 may be formed of, e.g., a ceramic insulator such as alumina.

The central electrode 110 may be provided extensively at an internal central portion of the body 101. For example, the central electrode 110 may have a relatively large circular plate shape corresponding to the wafer 2000 to be processed in a plasma process. The central electrode 110 may be a chucking electrode for electrically fixing the wafer 2000 to the ESC 100a. The central electrode 110 may also perform a function of applying bias to plasma. DC power or RF power may be supplied to the central electrode 110. DC power and RF power may be supplied in a pulse form.

The first tilting electrode 120 may correspond to the first plasma distribution control structure PCS1. The first tilting electrode 120 may be positioned at or near an edge of the inside of the body 101. As shown in FIG. 2A, the first tilting electrode 120 may have or be inclined at a first angle θ1 with respect to a top surface of the ESC 100a. The first tilting electrode 120 may have a tilt with respect to the top surface of the ESC 100a, and a distance between the top surface of the first tilting electrode 120 and the top surface of the ESC 100a may be different according to a (e.g., radial) position at the top surface of the first tilting electrode 120. For example, the top surface of the first tilting electrode 120 may be closer to the top surface of the ESC 100a in a direction from the center toward the edge of the ESC 100a.

The first tilting electrode 120 may be separated or spaced apart from the central electrode 110 in a horizontal direction, e.g., an X direction or the radial direction, and may be electrically independent or isolated. For example, the first tilting electrode 120 may be supplied with power through an additional power supply 160 separate from a main power supply (that supplies power to the central electrode 110). Accordingly, independent DC or RF power (different from DC or RF power supplied to the central electrode 110) may be supplied to the first tilting electrode 120.

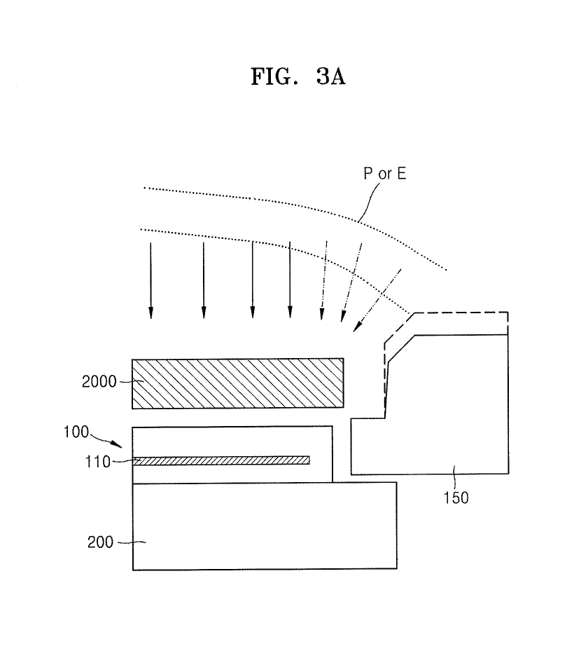

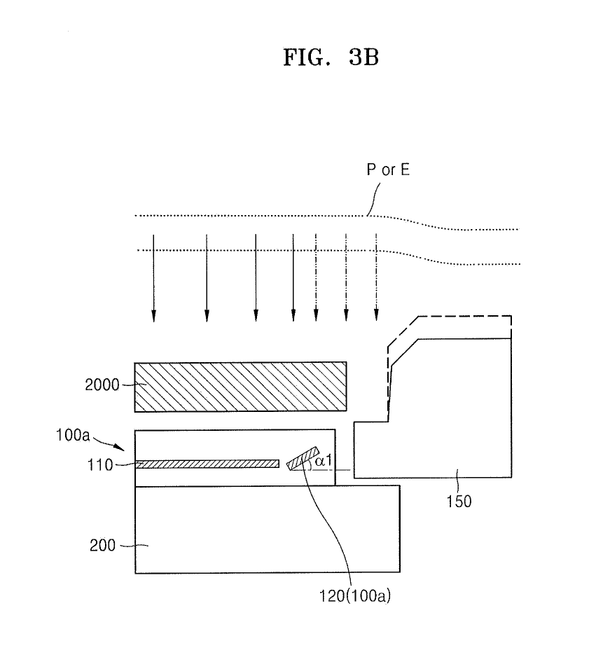

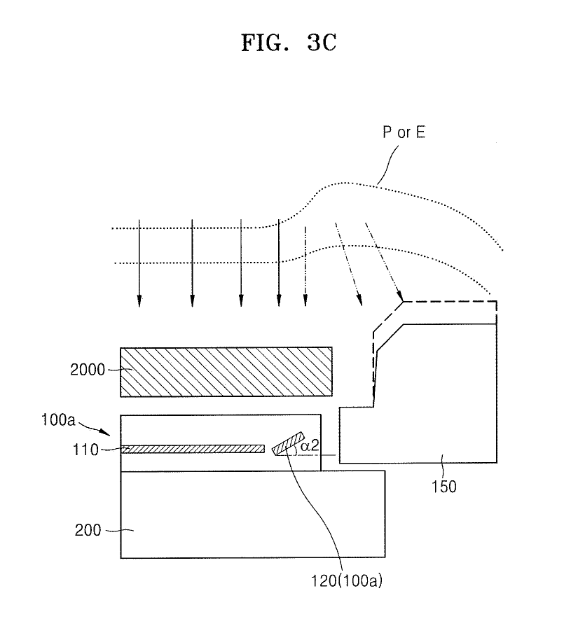

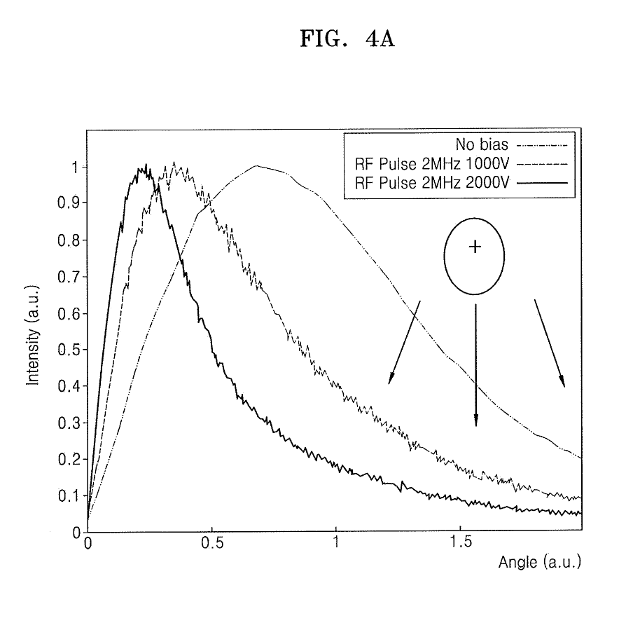

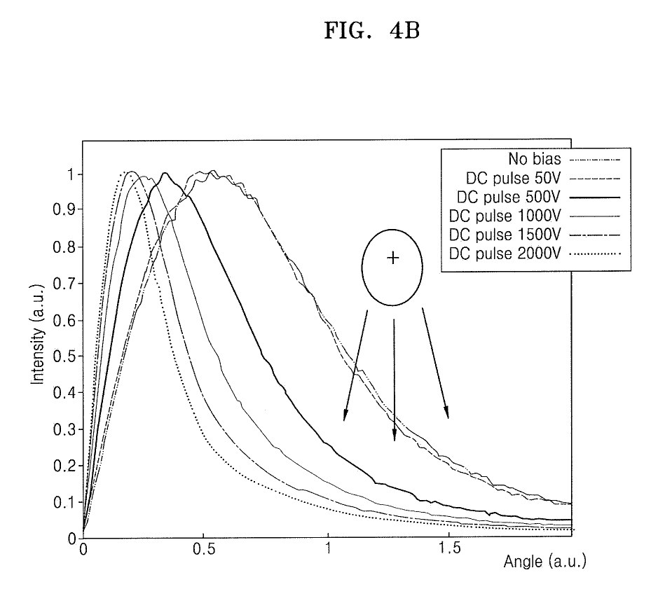

When the ESC 100a includes the first tilting electrode 120 as the first plasma distribution control structure PCS1, the plasma processing apparatus 1000a may help control the density of an E-field and/or plasma at an edge region inside the chamber 500, thereby preventing a nonuniform plasma distribution in the edge region. For example, when power is applied to the first tilting electrode 120 having the above-described structure, the E-field and/or plasma may be prevented from being concentrated on the edge region, and therefore, the distribution of plasma may be improved in the edge region. Plasma distribution control in the edge region using the first tilting electrode 120 will be described in detail with reference to FIGS. 3A through 4B below.

Referring to FIG. 2B, a plasma processing apparatus 1000b may be different from the plasma processing apparatus 1000a illustrated in FIG. 2A in that an ESC 100b includes a second tilting electrode 120a having a different structure than the first tilting electrode 120. For example, in the plasma processing apparatus 1000b, the ESC 100b may include the second tilting electrode 120a that is divided into a plurality of segments. In an implementation, the second tilting electrode 120a may include, e.g., three tilting electrode segments 120-1, 120-2, and 120-3.

The tilting electrode segments 120-1, 120-2, and 120-3 may be spaced apart from one another. For example, the tilting electrode segments 120-1, 120-2, and 120-3 may be electrically isolated from one another. Independent DC or RF power different from DC or RF power supplied to the central electrode 110 may be supplied from an additional power supply 160a to each of the tilting electrode segments 120-1, 120-2, and 120-3. In an implementation, DC or RF power supplied to each of the tilting electrode segments 120-1, 120-2, and 120-3 through the additional power supply 160a may be different and independent among the tilting electrode segments 120-1, 120-2, and 120-3. In an implementation, the same DC or RF power may be supplied to at least two of the tilting electrode segments 120-1, 120-2, and 120-3.

As shown in FIG. 2B, the tilting electrode segments 120-1, 120-2, and 120-3 may be arranged to be parallel with the top surface of the ESC 100b. However, the tilting electrode segments 120-1, 120-2, and 120-3 may be sequentially arranged in a vertical direction, i.e., a z direction, at different positions or heights, and therefore, the second tilting electrode 120a may have a tilt with respect to the top surface of the ESC 100b. For example, a line connecting centers of the respective tilting electrode segments 120-1, 120-2, and 120-3 may have or form a second angle θ2 with respect to the top surface of the ESC 100b.

When the ESC 100b includes the second tilting electrode 120a as the first plasma distribution control structure PCS1, the plasma processing apparatus 1000b may control the density of an E-field and/or plasma at an edge region inside the chamber 500, thereby preventing a nonuniform plasma distribution in the edge region.

Referring to FIG. 2C, a plasma processing apparatus 1000c may be different from the plasma processing apparatus 1000a illustrated in FIG. 2A in that an ESC 100c includes a third tilting electrode 120b having a different structure than the first tilting electrode 120. For example, in the plasma processing apparatus 1000c, the ESC 100c may include the third tilting electrode 120b having a stair-shaped structure. For example, the third tilting electrode 120b may have a stair-shaped structure in which a position or height in the vertical direction, i.e., the z direction, becomes higher in a direction from the center toward the edge of the ESC 100c.

The third tilting electrode 120b may be similar to the first tilting electrode 120 in that the third tilting electrode 120b may be formed integrally. The third tilting electrode 120b may also be similar to the first tilting electrode 120 in that independent DC or RF power different from DC or RF power supplied to the central electrode 110 may be supplied from one additional power supply 160 to the third tilting electrode 120b.

Meanwhile, the third tilting electrode 120b may be similar to the second tilting electrode 120a in that the third tilting electrode 120b may have flat top surfaces in the stair-shaped structure. For example, if the tilting electrode segments 120-1, 120-2, and 120-3 of the second tilting electrode 120a were extended in the horizontal direction, i.e., the x direction or radial direction, and connected to one another, the second tilting electrode 120a may have substantially the same structure as the third tilting electrode 120b.

When the ESC 100c includes the third tilting electrode 120b as the first plasma distribution control structure PCS1, the plasma processing apparatus 1000c may control the density of an E-field and/or plasma at an edge region inside the chamber 500, thereby preventing a nonuniform plasma distribution in the edge region.

FIGS. 3A through 3C illustrate conceptual diagrams showing a comparison of the effect of a plasma processing apparatus using the ESC structure illustrated in FIG. 2A to the effect of a plasma processing apparatus using an ESC not having a tilting electrode therewithin. For example, FIG. 3A shows a main portion of the plasma processing apparatus using an ESC not having a tilting electrode, and FIGS. 3B and 3C show a main portion of the plasma processing apparatus using the ESC structure illustrated in FIG. 2A in cases where tilting electrodes have different tilting angles, respectively. In FIGS. 3A through 3C, the arrows denote directions of an E-field, and dotted lines P or E are a sort of isopycnal lines showing density distributions of plasma or E-field.

Referring to FIG. 3A, as an upper portion of the edge ring 150 is removed by etching, the isopycnal lines P or E tilt toward an edge portion of the wafer 2000 and the direction of the E-field also tilts toward the edge portion of the wafer 2000. Here, the state of the edge ring 150 before the etching is marked with a broken or dashed line.

Consequently, in the plasma processing apparatus using the ESC not having a tilting electrode, a change may occur over time during a plasma etching process due to etching of the edge ring 150. For example, a nonuniform distribution of an E-field or plasma may occur in an internal chamber edge region corresponding to the edge portion of the wafer 2000. The nonuniform distribution of plasma in the edge region may cause an error in the plasma etching process, leading to a failure of a semiconductor device.

Referring to FIG. 3B, when the ESC 100a includes the first tilting electrode 120 (separately from the central electrode 110), the isopycnal lines P or E are level in the edge region inside the chamber 500 and an E-field has the vertical direction in the edge region as in the other region.

Consequently, in the plasma processing apparatus using the ESC 100a including the first tilting electrode 120, DC power or RF power may be supplied to the first tilting electrode 120, so that a change occurring over time may be prevented during a plasma etching process, despite of etching of the edge ring 150. For example, a nonuniform plasma distribution in the edge region inside the chamber 500 may be prevented.

Referring to FIG. 3C, an angle of the first tilting electrode 120 may be adjusted such that the isopycnal lines P or E are enhanced and expanded outwardly in the edge region inside the chamber 500 and the E-field has a direction tilting outwardly. In an implementation, a second tilting angle α2 of the first tilting electrode 120 shown in FIG. 3C may be greater than a first tilting angle α1 of the first tilting electrode 120 shown in FIG. 3B. In an implementation, a density distribution of plasma and the direction of an E-field with respect to a tilting angle may vary with supplied power and the shape of the edge ring 150.

FIGS. 4A and 4B illustrate graphs showing effects obtained when an RF pulse voltage and a DC pulse voltage are respectively applied to the first tilting electrode 120 in the plasma processing apparatus 1000a illustrated in FIG. 2A. In the graphs, the X-axis indicates an angle of an E-field with respect to the vertical direction, the Y-axis indicates the intensity of the E-field, and an arbitrary unit may be used for the angle and the intensity. In analyzing the graphs, when the intensity increases toward the left of the graphs, it may mean that most of angles of an E-field are small, and therefore, the E-field is nearly directed in the vertical direction. When the intensity increases toward the right of the graphs, it may mean that some angles of the E-field are large, and therefore, the E-field is partially tilted toward the horizontal direction.

Referring to FIGS. 4A and 4B, the intensity of an E-field at a small angle may be greater when a DC pulse voltage is applied than when an RF pulse voltage is applied, and therefore, the E-field may be more likely to be directed in the vertical direction when the DC pulse voltage is applied. For example, when an RF pulse voltage and a DC pulse voltage are applied at a voltage of 2,000 V, a graph corresponding to the DC pulse voltage may be more biased to the left than a graphs corresponding to the RF pulse voltage, and therefore, the E-field may be more likely to be directed in the vertical direction when the DC pulse voltage is applied.

In the graphs shown in FIGS. 4A and 4B, the directions of the E-field are shown by the arrows. For example, the directions of the E-field may be directed downward with a little tilt to the right and to the left in the graph shown in FIG. 4A, and most of the directions of the E-field may be directed vertically downward in the graph shown in FIG. 4B.

Meanwhile, the graph of a DC pulse voltage or an RF pulse voltage may be more biased to the left when a bias voltage is applied than when a bias voltage is not applied and is more biased to the left as the bias voltage increases. This result may be inferred from the relation between an E-field and a voltage, to some extent.

Consequently, when DC pulse power is supplied to the first tilting electrode 120 in the plasma processing apparatus 1000a, a nonuniform plasma distribution in the edge region may be effectively prevented. In an implementation, results of supplying DC pulse power and RF pulse power to the first tilting electrode 120 may vary with the shape of the edge ring 150 or RF power supplied from the coil antenna 600.

FIGS. 5A through 5D illustrate cross-sectional views and plan views of an ESC support structure applicable to a plasma processing apparatus, according to an embodiment. FIG. 5B corresponds to FIG. 5A, and a first level and a second level of the ESC support structure are respectively shown in the right and left of FIG. 5B. FIG. 5D corresponds to FIG. 5C, and the first level and the second level of the ESC support structure are respectively shown in the right and left of FIG. 5D. Redundant descriptions that have been made with reference to FIGS. 1 through 2C may be briefly stated or omitted.

Referring to FIGS. 5A through 5D, in a plasma processing apparatus 1000d, an ESC support 200a may include a metal-containing or metal plate 201, an insertion body 210, a dielectric insertion layer 220, and a high-k dielectric 230. Meanwhile, a power-applying electrode 250 may be provided penetrating through the insertion body 210 at the center of the ESC support 200a.

The metal plate 201 may be positioned right below the ESC 100 to support the ESC 100. The metal plate 201 may correspond to an ESC support in other types of plasma processing apparatuses. In an implementation, the metal plate 201 may be formed of, e.g., aluminum. In an implementation, the metal plate 201 may be formed of an insulator such as alumina.

The insertion body 210 may be positioned below the metal plate 201 (e.g., opposite to the ESC 100) and may have the dielectric insertion layer 220 formed therein, the dielectric insertion layer 220 corresponding to an empty space therein. The insertion body 210 may be formed of an insulator. In an implementation, the insertion body 210 may be formed of, e.g., alumina. In an implementation, when both the metal plate 201 and the insertion body 210 are formed of alumina, the metal plate 201 and the insertion body 210 may be formed integrally and thus not be distinguished from each other.

The dielectric insertion layer 220 may have two levels inside the insertion body 210. In an implementation, the dielectric insertion layer 220 may include a first dielectric insertion layer 220-1 at a lower level (e.g., distal to the ESC 100) and a second dielectric insertion layer 220-2 at an upper level (e.g., proximate to the ESC 100). In an implementation, the dielectric insertion layer 220 may have, e.g., a single level or at least three levels.

In an implementation, the first dielectric insertion layer 220-1 and the second dielectric insertion layer 220-2 may be segmented into, e.g., four, sections in a circumferential direction by a barrier wall 215. The barrier wall 215 may be part of the insertion body 210. In an implementation, the first dielectric insertion layer 220-1 and the second dielectric insertion layer 220-2 may be segmented into, e.g., two or three sections or at least five sections. In an implementation, the first dielectric insertion layer 220-1 may be segmented differently than the second dielectric insertion layer 220-2. In an implementation, the first dielectric insertion layer 220-1 may be segmented into three sections and the second dielectric insertion layer 220-2 may be segmented into four sections.

The high-k dielectric 230 may be provided in a solid state at the dielectric insertion layer 220 and may be movable inside the dielectric insertion layer 220. When the dielectric insertion layer 220 has two levels and is segmented into four sections at each level, the high-k dielectric 230 may include a first high-k dielectric 230-1 and a second high-k dielectric 230-2 which are segmented into four sections, corresponding to the dielectric insertion layer 220.

The high-k dielectric 230 may be opposite to a low-k dielectric and may be defined as a material having higher permittivity than silicon oxide (SiO₂) having a relative permittivity of about 3.9 to about 4.2. In an implementation, the high-k dielectric 230 may include alumina, polytetrafluoroethylene (PTFE)-ceramic, or silicon. The high-k dielectric 230 may be formed of a hafnium (Hf)-based or zirconium (Zr)-based material. In an implementation, the high-k dielectric 230 may include hafnium oxide (HfO₂), hafnium silicon oxide (HfSiO), hafnium silicon oxynitride (HfSiON), hafnium oxynitride (HfON), hafnium aluminum oxide (HfAlO), hafnium lanthanum oxide (HfLaO), zirconium oxide (ZrO₂), or zirconium silicon oxide (ZrSiO). In an implementation, the high-k dielectric 230 may include other material such as lanthanum oxide (La₂O₃), lanthanum aluminum oxide (LaAlO₃), tantalum oxide (Ta₂O₅), titanium oxide (TiO₂), strontium titanium oxide (SrTiO₃), yttrium oxide (Y₂O₃), red scandium tantalum oxide (PbSc_{0.5}Ta_{0.5}O₃), or red zinc niobate (PbZnNbO₃).

Permittivity of dielectric materials may usually decrease as a frequency increases. Permittivity of dielectric materials in a solid state may increase as temperature increases. Contrarily, permittivity of dielectric materials in a fluid state may decrease as temperature increases.

As shown in FIGS. 5A and 5B, when the high-k dielectric 230 is arranged in a balanced state of permittivity at a central portion and an edge portion, e.g., when the first high-k dielectric 230-1 is positioned at the central portion in the first dielectric insertion layer 220-1 and the second high-k dielectric 230-2 is positioned at the edge portion in the second dielectric insertion layer 220-2, and a height difference in the arrangement is not considered, it may be seen from a horizontal viewpoint that permittivity is balanced between the central portion and the edge portion. Meanwhile, when the first high-k dielectric 230-1 is positioned at the edge portion in the first dielectric insertion layer 220-1 and the second high-k dielectric 230-2 is positioned at the central portion in the second dielectric insertion layer 220-2, it may also correspond to the balanced state of permittivity.

In the balanced state of permittivity, the density of an E-field and/or plasma above the wafer 2000 may be uniform and the distribution thereof may also be uniform. However, when the edge ring 150 (see FIG. 1) is etched during a plasma process, the density of an E-field and/or plasma above an edge of the wafer 2000 may be not uniform, causing a nonuniform distribution of plasma.

As shown in FIGS. 5C and 5D, when the first high-k dielectric 230-1 is moved to the edge portion, as shown by the arrows, in the first dielectric insertion layer 220-1, the edge portion may be in a high-permittivity state. For example, when the first high-k dielectric 230-1 and the second high-k dielectric 230-2 are positioned at the edge portion in the first dielectric insertion layer 220-1 and the second dielectric insertion layer 220-2, respectively, it may be seen from the horizontal viewpoint that permittivity is higher in the edge portion than in the central portion. When the permittivity increases in the edge portion, the density of an E-field and/or plasma above the edge of the wafer 2000 may be uniform and the distribution of plasma may be improved.

In the plasma processing apparatus 1000d, the high-k dielectric 230 may be in a solid state and may be movable between the central portion and the edge portion in the dielectric insertion layer 220. In an implementation, the plasma processing apparatus 1000d may include a mover that moves the high-k dielectric 230 in a solid state. In an implementation, the high-k dielectric 230 may be manually movable in the dielectric insertion layer 220.

When the ESC support 200a includes the dielectric insertion layer 220 and the high-k dielectric 230 movable in a solid state as the second plasma distribution control structure PCS2, the plasma processing apparatus 1000d may control the density of an E-field and/or plasma at an edge region inside the chamber 500, thereby preventing a nonuniform plasma distribution in the edge region. For example, when the ESC support 200a having the structure shown in FIGS. 5C and 5D is implemented, the distribution of plasma may be improved in the edge region, and therefore, the E-field and/or plasma is prevented to be concentrated on the edge of the wafer 2000.

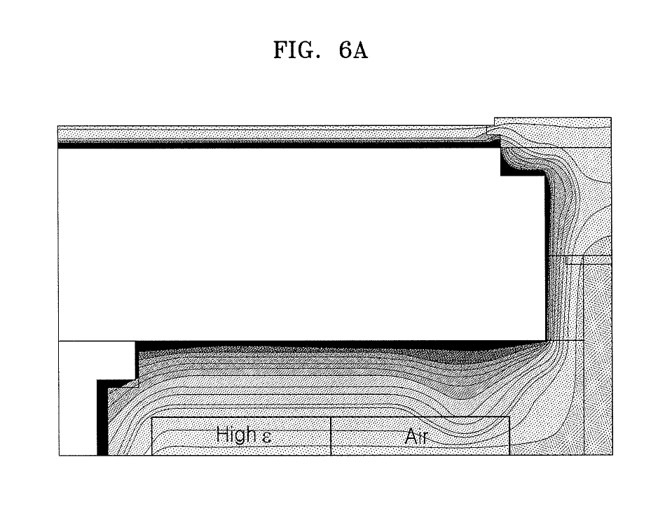

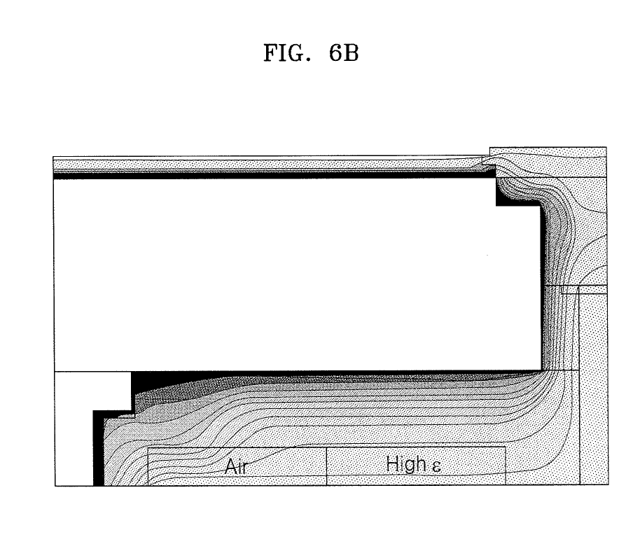

FIGS. 6A and 6B illustrate conceptual diagrams of the effects of a plasma processing apparatus using the ESC support structure illustrated in FIGS. 5A and 5C. FIGS. 6A and 6B show the right half side of an ESC support and a density gradient of an E-field and/or plasma.

Referring to FIGS. 6A and 6B, the density of an E-field and/or plasma may be biasedly high at the edge portion when a high-k dielectric is positioned at the central portion, as shown in FIG. 6A. This state may be similar to a phenomenon occurring when the upper portion of the edge ring 150 (see FIG. 1) is removed as shown in FIG. 3A.

Meanwhile, as shown in FIG. 6B, when the high-k dielectric is positioned at the edge portion, the density of an E-field and/or plasma biased to the edge portion may become uniform. This state may be similar to the result of supplying power to a tilting electrode, as shown in FIG. 3B.

Consequently, when the density of an E-field and/or plasma is biased to an edge portion, causing a nonuniform plasma distribution in an edge region, it may be expected that the nonuniform plasma distribution at the edge region may be improved by producing a high permittivity state at the edge portion by positioning a high-k dielectric material at the edge portion.

For reference, when permittivity of a support layer below a wafer is decreased, and therefore, impedance is increased, a current flowing in the support layer may decrease while a current transmitted to plasma may increase, so that the density of plasma increases. Contrarily, when the permittivity of the support layer is increased, and therefore, the impedance is decreased, the current flowing in the support layer increases while the current transmitted to the plasma decreases, so that the density of plasma may decrease. When permittivity of the edge portion inside the ESC support 200 is changed based on this principle, the density of plasma and the distribution of plasma corresponding thereto may be controlled at the edge region inside the chamber 500.

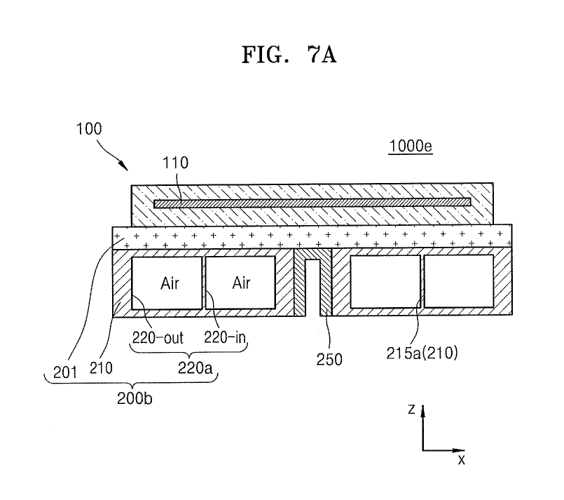

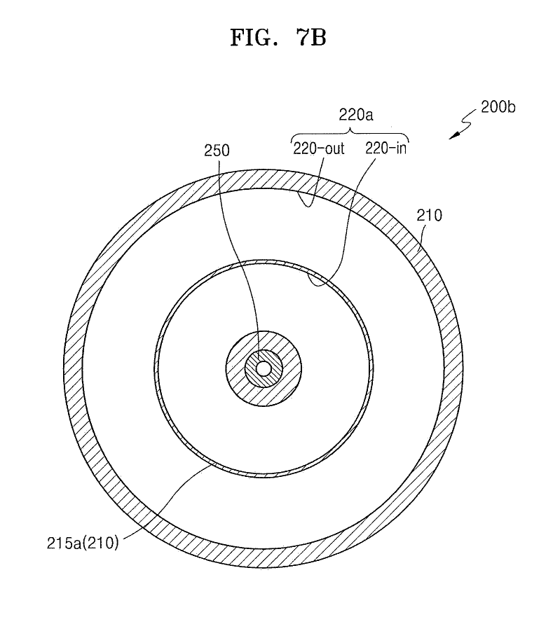

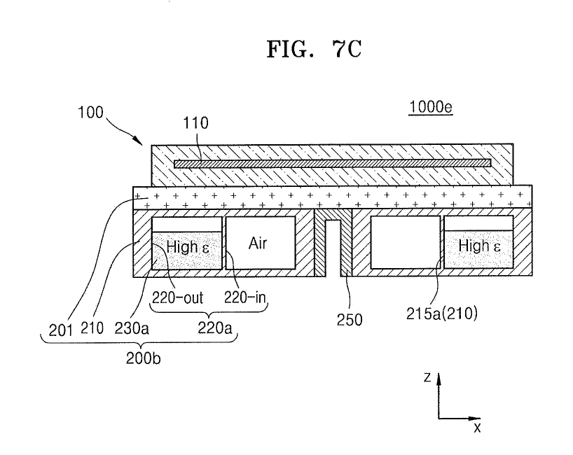

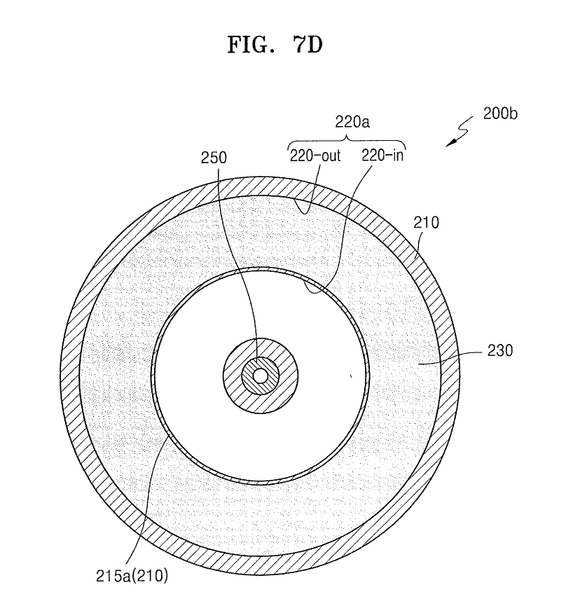

FIGS. 7A through 7D are cross-sectional views and plan views of an ESC support structure applicable to a plasma processing apparatus, according to another embodiment. FIG. 7B corresponds to FIG. 7A and FIG. 7D corresponding to FIG. 7C. Redundant descriptions that have been made with reference to FIGS. 5A through 6B may be briefly stated or omitted.

Referring to FIGS. 7A through 7D, a plasma processing apparatus 1000e may be different from the plasma processing apparatus 1000d shown in FIG. 5A in the structure of an ESC support 200b and a dielectric insertion layer 220a and the state of a high-k dielectric 230a. For example, in the plasma processing apparatus 1000e, the dielectric insertion layer 220a of the ESC support 200b may be divided into an inner dielectric insertion layer 220-in and an outer dielectric insertion layer 220-out by a barrier wall 215a. The dielectric insertion layer 220a may be formed in a single level. In an implementation, the dielectric insertion layer 220a may be formed to have multiple levels such as two levels or three levels.

In the plasma processing apparatus 1000e, the high-k dielectric 230a may be in a fluid state like gas or liquid. Accordingly, permittivity of the dielectric insertion layer 220a may be controlled by controlling the level of the high-k dielectric 230a when the high-k dielectric 230a is supplied to the dielectric insertion layer 220a.

For example, when the high-k dielectric 230a is not supplied to any of the inner dielectric insertion layer 220-in and the outer dielectric insertion layer 220-out, as shown in FIGS. 7A and 7B, permittivity may be balanced between the central portion and the edge portion. In other cases where the inner dielectric insertion layer 220-in and the outer dielectric insertion layer 220-out are both fully filled or partially filled to the same amount with the high-k dielectric 230a, the balanced state of permittivity may be achieved.

Meanwhile, when the high-k dielectric 230a is supplied to only the outer dielectric insertion layer 220-out as shown in FIGS. 7C and 7D, the edge portion may be in a high-permittivity state. In addition, a permittivity difference between the central portion and the edge portion may be controlled by controlling the amount of the high-k dielectric 230a supplied to the outer dielectric insertion layer 220-out. As described above, in case where a nonuniform plasma distribution occurs because an E-field and/or plasma is concentrated in the edge portion due to etching of an edge ring, when the edge portion is changed into a high-permittivity state, the E-field and/or plasma becomes uniform in an edge region, so that the nonuniform plasma distribution may be improved.

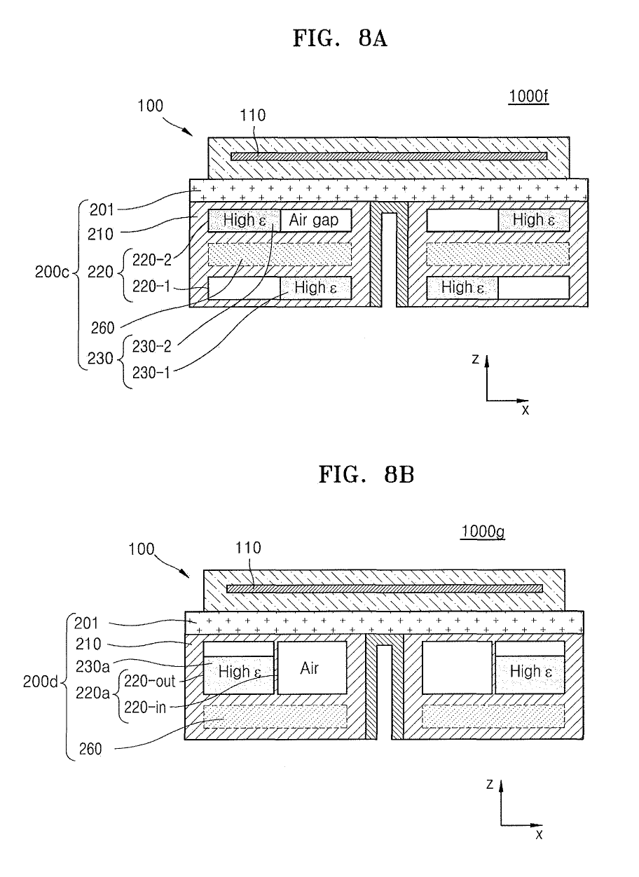

FIGS. 8A and 8B illustrate cross-sectional views of an ESC support structure applicable to plasma processing apparatuses, respectively, according to an embodiment. Redundant descriptions that have been made with reference to FIGS. 5A through 7D may be briefly stated or omitted.

Referring to FIG. 8A, a plasma processing apparatus 1000f may be different from the plasma processing apparatus 1000d shown in FIG. 5A in that an ESC support 200c may further include a heating element 260. For example, in the plasma processing apparatus 1000f, the ESC support 200c may include the heating element 260 such as a filament heater between the first dielectric insertion layer 220-1 and the second dielectric insertion layer 220-2. In an implementation, the heating element 260 may be provided at various positions inside the ESC support 200c. For example, the heating element 260 may be positioned to effectively heat the high-k dielectric 230. The heating element 260 may also be separately provided to correspond to the first high-k dielectric 230-1 and the second high-k dielectric 230-2. The heating element 260 may also be moved in response to the movement of the first high-k dielectric 230-1 and the second high-k dielectric 230-2.

As described above, permittivity of dielectric materials in a solid state may increase as temperature increases. Accordingly, when dielectric in a solid state is inserted to fully fill the dielectric insertion layer 220 and the edge portion of the dielectric is heated using the heating element 260, the edge portion may be changed into a high-permittivity state.

Referring to FIG. 8B, a plasma processing apparatus 1000g may be different from the plasma processing apparatus 1000e shown in FIG. 7A in that an ESC support 200d may further include the heating element 260. For example, in the plasma processing apparatus 1000g, the ESC support 200d may include the heating element 260 below the dielectric insertion layer 220a. In an implementation, the heating element 260 may be provided at a position allowing the heating element 260 to effectively heat the high-k dielectric 230a. For example, the heating element 260 may be positioned above or beside the dielectric insertion layer 220a.

As described above, permittivity of dielectric materials in a fluid state may decrease as temperature increases. Accordingly, when the high-k dielectric 230a in a fluid state is supplied to both the inner dielectric insertion layer 220-in and the outer dielectric insertion layer 220-out and the high-k dielectric 230a only in the inner dielectric insertion layer 220-in may be heated using the heating element 260, permittivity of the central portion may be decreased, and therefore, the edge portion may be changed into a high-permittivity state.

FIGS. 9A and 9B illustrate cross-sectional views of a window structure applicable to a plasma processing apparatus, according to an embodiment. Redundant descriptions that have been made with reference to FIG. 1 may be briefly stated or omitted.

Referring to FIGS. 9A and 9B, in a plasma processing apparatus 1000h, a coil insertion groove 420 may be formed at an edge of the top surface of a window 400a (e.g., facing away from the reaction space). In addition, a coil antenna 600a may also include an additional coil 630 provided at the coil insertion groove 420 of the window 400a. The additional coil 630 may also be connected to the RF power supply 700. The RF power supplied to the additional coil 630 may be different from RF power supplied to the inner coil 610 and/or the outer coil 620. As described above, when the RF power is independently supplied using the additional coil 630 provided at the coil insertion groove 420 of the window 400a, an E-field and/or plasma may be spread outward in the edge region inside the chamber 500 (see FIG. 1). Accordingly, a plasma distribution in the edge region inside the chamber 500 may be improved.

As shown in FIG. 9A, the coil insertion groove 420 may be formed further out from a center of the window 400a than the outer coil 620 in the horizontal direction, i.e., the x direction or radial direction, and therefore, the additional coil 630 may be positioned further out from the center of the window 400a than the outer coil 620 in the horizontal direction, i.e., the X direction or radial direction. For example, the additional coil 630 may be positioned further out from the center relative to the outer coil 620 by a first distance D1 in the horizontal direction, i.e., the X direction. In an implementation, the position of the coil insertion groove 420 in the horizontal direction, i.e., the X direction, may be adjusted to be substantially the same as or to be closer to the center of the window 400a than the position of the outer coil 620 in the horizontal direction, i.e., the X direction or radial direction.

The plasma processing apparatus 1000h may include a mover that moves the additional coil 630 in the vertical direction, i.e., the Z direction (e.g., toward and away from the reaction space). Accordingly, the additional coil 630 may be moved in the vertical direction, i.e., the Z direction, as shown in FIG. 9B. In an implementation, when the additional coil 630 is positioned deep in the coil insertion groove 420, e.g., when the additional coil 630 is close to the inside of the chamber 500 or the reaction space, an improvement made in a plasma distribution by the additional coil 630 in the edge region may be increased. Contrarily, when the additional coil 630 is positioned shallow in the coil insertion groove 420, e.g., when the additional coil 630 is far from the inside of the chamber 500 or reaction space, an improvement made in a plasma distribution by the additional coil 630 in the edge region may be decreased. The plasma processing apparatus 1000h may more precisely control the plasma distribution in the edge region inside the chamber 500 by controlling the position of the additional coil 630 in the vertical direction, i.e., the Z direction.

Meanwhile, the coil insertion groove 420 may be formed at the edge of the top surface of the window 400a in the plasma processing apparatus 1000h, as described above. Accordingly, the coil insertion groove 420 and the additional coil 630 may not be in contact with plasma generated inside the chamber 500 and thus may be prevented from being damaged or contaminated by the plasma.

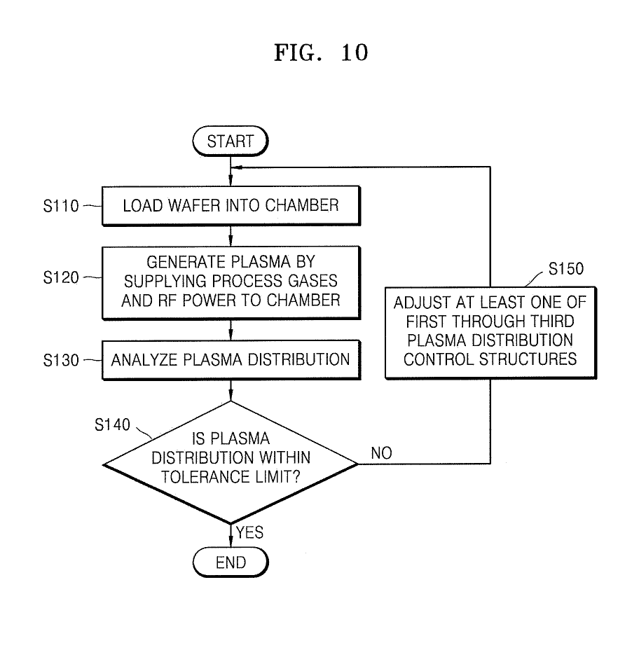

FIG. 10 illustrates a flowchart of a method of controlling the distribution of plasma, according to an embodiment. The method will be described with reference to FIGS. 1 through 2C, FIGS. SA through SD, and FIGS. 7A through 9B together. Descriptions already made may be briefly stated or omitted.

Referring to FIG. 10, the wafer 2000 may be positioned on the ESC 100 inside the chamber 500 of the plasma processing apparatus 1000 in operation S110. The plasma processing apparatus 1000 may include the ESC 100 including the first plasma distribution control structure PCS1, the ESC support 200 including the second plasma distribution control structure PCS2, and/or a group of the window 400 and the coil antenna 600, which includes the third plasma distribution control structure PCS3. In an implementation, the plasma processing apparatus 1000 may be any one of the plasma processing apparatuses 1000a through 1000h illustrated in FIG. 1, FIGS. 2A through 2C, FIGS. 5A through 5D, and FIGS. 7A through 9B.

The wafer 2000 may be a device wafer on which a plasma process is to be actually performed to manufacture a plurality of semiconductor chips. In an implementation, the wafer 2000 may be a dummy wafer used to analyze the distribution of plasma in an edge region inside the chamber 500. For example, after the distribution of plasma inside the chamber 500 and the uniformity of plasma corresponding to the distribution are checked using a dummy wafer, a normal device wafer may be loaded into the chamber 500 and subjected to the plasma process.

Thereafter, process gases and RF power may be supplied to the chamber 500 to generate plasma in operation S120. The process gases may be provided to a gas ejection head of the chamber 500 through a supply pipe and may be ejected from the gas ejection head into the chamber 500. The RF power may be supplied from the RF power supply 700 to the coil antenna 600 through the wiring circuit 750. Together with the supply of the RF power, DC power or RF power may be supplied to the electrodes 110 and 120 (see FIG. 2A) of the ESC 100.

At this time, the generating of the plasma may refer to performing a plasma process on the wafer 2000 using the generated plasma. The plasma process may include performing etching, deposition, diffusion, or surface treatment on the wafer 2000. In an implementation, plasma may be used for a light source or synthesis of a new material.

For reference, plasma may be classified into low-temperature plasma and thermal plasma. Low-temperature plasma may be used in semiconductor processes such as semiconductor manufacturing, metal and ceramic thin film manufacturing, and material synthesis. Thermal plasma may be used to cut metals. Low-temperature plasma may be classified into atmospheric plasma, vacuum plasma, and next-generation plasma according to the fields of application. Vacuum plasma technology is generating low-temperature plasma with a gas pressure maintained at 100 Torr or less. The vacuum plasma technology may be used for dry etch, thin film deposition, photoresist (PR) ashing, atomic layer deposition (ALD) growth, etc. in a semiconductor process and may be used for etching or thin film deposition on a display panel in a display process.

Meanwhile, plasma may be classified into capacitively coupled plasma (CCP), inductively coupled plasma (ICP), electron cyclotron resonance (ECR) plasma, surface wave plasma (SWP), helicon wave plasma, and e-beam plasma according to plasma generating methods. In an implementation, the plasma processing apparatus 1000 may be an ICP processing apparatus, and therefore, plasma generated in the plasma processing apparatus 1000 may be ICP.

In the method of controlling the distribution of plasma, the plasma processing apparatus 1000 may include the ESC 100 including the first plasma distribution control structure PCS1, the ESC support 200 including the second plasma distribution control structure PCS2, and/or a group of the window 400 and the coil antenna 600, which includes the third plasma distribution control structure PCS3, and therefore, the distribution of plasma inside the chamber 500, and more particularly, the distribution of plasma in the edge region inside the chamber 500 is improved. As a result, the plasma process may be stably performed.

Thereafter, the distribution of plasma inside the chamber 500 may be analyzed in operation S130. The analysis of the plasma distribution may be performed during or after the plasma process. The plasma distribution may be analyzed in an analyzer using an analysis program. For example, the analysis of the plasma distribution may be performed by detecting plasma inside the chamber 500 using a probe or an OES device, which may be coupled to a viewport of the chamber 500, and analyzing the density and distribution of the plasma based on detected plasma data using the analysis program in the analyzer.

The analysis of the plasma distribution may be performed after the plasma process through measurement of the wafer 2000. For example, when etching or deposition is performed using plasma, an etched state or a deposition state of the wafer 2000 may be measured, and the analyzer may calculate the density of plasma inside the chamber 500 based on measured data using the analysis program to analyze the plasma distribution.

After the analysis of the plasma distribution, whether the plasma distribution is within a tolerance limit may be determined in operation S140. The determination may be performed by the analyzer. For example, the analyzer may prepare reference data for the plasma distribution in the plasma process and may compare the reference data with the analyzed plasma distribution to determine whether the plasma distribution is within the tolerance limit.

When the plasma distribution is within the tolerance limit (i.e., in case of YES), the method ends. When the plasma distribution is beyond the tolerance limit (i.e., in case of NO), the first through third plasma distribution control structures PCS1, PCS2, and/or PCS3 may be adjusted to control the plasma distribution in operation S150. For example, when the first plasma distribution control structure PCS1 is adjusted, the angle of the first tilting electrode 120 (see FIG. 2A) or the DC or RF power supplied to the tilting electrode 120 may be adjusted. When the second plasma distribution control structure PCS2 is adjusted, the position or permittivity of the high-k dielectric 230 (see FIG. 5A) of the dielectric insertion layer 220 (see FIG. 5A) may be adjusted. When the third plasma distribution control structure PCS3 is adjusted, the vertical position of the additional coil 630 (see FIG. 9A) or the RF power supplied to the additional coil 630 may be adjusted.

Meanwhile, the adjustment of the first through third plasma distribution control structures PCS1, PCS2, and/or PCS3 may be based on E-field and/or plasma density analyzed by the analyzer. After the adjustment of the first through third plasma distribution control structures PCS1, PCS2, and PCS3, the method may go back to load a wafer into the chamber 500 in operation S110, to generate plasma in operation S120, and to analyze a plasma distribution in operation S130.

The method of controlling the distribution of plasma may perform a plasma process using the plasma processing apparatus 1000 which includes the ESC 100 including the first plasma distribution control structure PCS1, the ESC support 200 including the second plasma distribution control structure PCS2, and/or the group of the window 400 and the coil antenna 600, which includes the third plasma distribution control structure PCS3, thereby precisely controlling the distribution of plasma in an edge region during the plasma process. As a result, due to the improved plasma distribution in the edge region, the method may contribute to the stability of the plasma process and thus to the manufacture of excellent and reliable semiconductor devices.

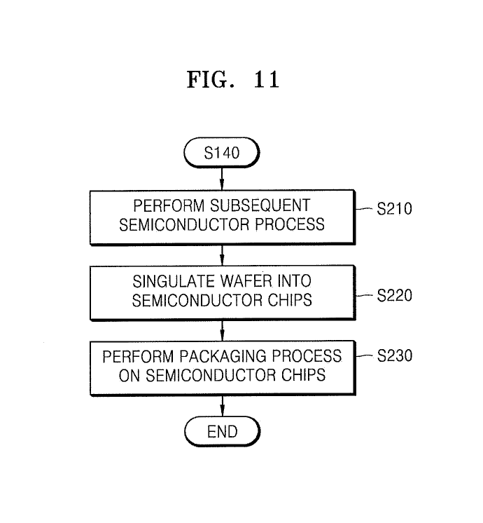

FIG. 11 illustrates a flowchart of a procedure for manufacturing a semiconductor device using the method illustrated in FIG. 10, according to an embodiment. Redundant descriptions that have been made with reference to FIG. 10 may be briefly stated or omitted.

Referring to FIG. 11, the plasma distribution control method described with reference to FIG. 10 may be performed. The plasma distribution control method may include a plasma process performed on the wafer 2000. For example, the generating of the plasma in operation S120 may correspond to the plasma process on the wafer 2000.

In FIG. 11, “S140” denotes performing the plasma distribution control method illustrated in FIG. 10, and the arrow from “S140” denotes progressing to a subsequent operation when the plasma distribution control method has ended, and more particularly, to progress to a subsequent operation when the plasma distribution control method has ended because the plasma distribution has been within the tolerance limit. The plasma distribution control method may be for normal device wafers.

A subsequent semiconductor process may be performed on the wafer 2000 in operation S210. The subsequent semiconductor process on the wafer 2000 may include various processes. For example, the subsequent semiconductor process on the wafer 2000 may include a deposition process, an etching process, an ion process, and/or a cleaning process. The deposition process, the etching process, the ion process, and the cleaning process may or may not use plasma. When the processes use plasma, the plasma distribution control method described above may be applied to the processes. Integrated circuits and interconnection lines required for semiconductor devices may be formed by performing the subsequent semiconductor process on the wafer 2000. The subsequent semiconductor process may also include a process of testing semiconductor devices at a wafer level.

The wafer 2000 may be singulated or cut into semiconductor chips in operation S220. The singulation may be implemented by performing a sawing process using a blade or a laser.

Thereafter, a packaging process may be performed on the semiconductor chips in operation S230. The packaging process may refer to a process of mounting a semiconductor chip on a printed circuit board (PCB) and sealing the semiconductor chip with a sealing material. The packaging process may include forming a stack package by stacking a plurality of semiconductor chips in multiple layers on a PCB or forming a package-on-package (POP) structure by stacking a plurality of stack packages. A semiconductor device or a semiconductor package may be completed through the packaging process. In an implementation, after the packaging process, a testing process may be performed on a semiconductor package.

In a method of manufacturing a semiconductor device according to the current embodiment, a plasma process may be performed using one of the plasma processing apparatuses 1000 and 1000a through 1000h illustrated in FIGS. 1 through 2C, FIGS. 5A through 5D, and FIGS. 7A through 9B, so that the plasma process may be optimized, and therefore, excellent and reliable semiconductor devices may be manufactured. For example, the semiconductor device manufacturing method may perform a plasma process using a plasma processing apparatus including the ESC 100 including the first plasma distribution control structure PCS1, the ESC support 200 including the second plasma distribution control structure PCS2, and/or the group of the window 400 and the coil antenna 600, which includes the third plasma distribution control structure PCS3, thereby improving the distribution of plasma in an edge region inside the chamber 500 and thus optimizing the plasma process. As a result, excellent and reliable semiconductor devices may be realized due to the optimized plasma process.

By way of summation and review, capacitively coupled plasma (CCP), inductively coupled plasma (ICP), helicon plasma, or microwave plasma may be used. A plasma process may be directly related to plasma parameters (e.g., electron density, electron temperature, ion flux, and ion energy). For example, plasma density and plasma uniformity may be closely related to throughput.

The embodiments may provide a plasma processing apparatus for controlling a distribution of plasma in an edge region of a chamber during a plasma process, thereby reliably performing the plasma process on a semiconductor substrate.

The embodiments may provide an apparatus for manufacturing a semiconductor device, and more particularly, to a plasma processing apparatus performing processes using plasma.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. An apparatus for plasma processing an object, the apparatus comprising:
a chamber that includes an outer wall and a window, the outer wall defining a reaction space in which plasma is formed, and the window covering an upper portion of the outer wall;
a coil antenna positioned above the window, the coil antenna including at least two coils; and
an electrostatic chuck (ESC) positioned in a lower portion of the chamber,
wherein:
the object to be processed is supportable on a top surface of the ESC and an electrode is located inside the ESC, and
the electrode includes a first electrode for holding the object and at least one second electrode, the first electrode provided in an internal central portion of the ESC so as to be parallel with the top surface of the ESC, and the at least one second electrode provided at an edge of the inside of the ESC so as to have a tilt with respect to the top surface of the ESC.

2. The apparatus as claimed in claim 1, wherein one of direct current (DC) power and radio frequency (RF) power is supplied to the at least one second electrode independently from the first electrode.

3. The apparatus as claimed in claim 1, wherein:
the at least one second electrode has a single integral structure, and
the single integral structure is a plate-shaped tilting structure or a stair-shaped tilting structure.

4. The apparatus as claimed in claim 1, wherein:
the at least one second electrode includes a plurality of segments in a stair-shaped tilting structure, and
direct current (DC) power or radio frequency (RF) power is independently supplyable to each segment of the plurality of segments.

5. The apparatus as claimed in claim 1, wherein the at least one second electrode is farther away from the top surface of the ESC in a direction from the edge toward the center of the ESC.

6. The apparatus as claimed in claim 1, further comprising an ESC support configured to support the ESC, wherein:
a dielectric insertion layer is formed inside the ESC support, and
a high-k dielectric in a solid state or a fluid state is provided in the dielectric insertion layer.

7. The apparatus as claimed in claim 6, wherein:
the dielectric insertion layer has two levels; and
the high-k dielectric is in the solid state, is provided in each of the two levels of the dielectric insertion layer, and is moveable between a central portion and an edge portion of the dielectric insertion layer.

8. The apparatus as claimed in claim 6, wherein:
the dielectric insertion layer is divided into a central portion and an edge portion by a barrier wall; and
the high-k dielectric is in the fluid state and injected into the central portion or the edge portion, and a level of the high-k dielectric is adjustable.

9. The apparatus as claimed in claim 6, wherein:
the window includes a groove at an edge of a top surface thereof, and
an additional coil of the coil antenna is in the groove and is configured to move up and down within the groove.

10. The apparatus as claimed in claim 1, wherein:
the at least two coils includes an inner coil, an outer coil, and an additional coil;
the window includes a groove at an edge of a top surface thereof; and
the additional coil is in the groove.

11. The apparatus as claimed in claim 10, wherein the additional coil is configured to move up and down within the groove.

12. An apparatus for plasma processing an object, the apparatus comprising:
a chamber that includes an outer wall and a window, the outer wall defining a reaction space in which plasma is formed, and the window covering an upper portion of the outer wall;
a coil antenna positioned above the window, the coil antenna including at least two coils;
an electrostatic chuck (ESC) positioned in a lower portion of the chamber; and
an ESC support configured to support the ESC,
wherein:
the object to be processed is supportable on a top surface of the ESC and an electrode is located inside the ESC; and
a dielectric insertion layer is formed inside the ESC support, and
a high-k dielectric in a solid state or a fluid state is provided in the dielectric insertion layer to be moveable or to be adjustable in level.

13. The apparatus as claimed in claim 12, wherein:
the dielectric insertion layer has two levels; and
the high-k dielectric is in the solid state, is provided in each of the two levels of the dielectric insertion layer, and is moveable between a central portion and an edge portion of the dielectric insertion layer.

14. The apparatus as claimed in claim 12, wherein:
the dielectric insertion layer is divided into a central portion and an edge portion by a barrier wall; and
the high-k dielectric is in the fluid state and injected into the central portion or the edge portion, and the level of the high-k dielectric is adjustable.

15. The apparatus as claimed in claim 12, wherein:
the ESC support includes a heating element provided adjacent to the dielectric insertion layer, and
a temperature of the high-k dielectric is adjustable through the heating element.

16. The apparatus as claimed in claim 12, wherein:
the electrode includes a first electrode for holding the object and at least one second electrode, the first electrode being provided in an internal central portion of the ESC so as to be parallel with the top surface of the ESC, and the at least one second electrode being provided at an edge of the inside of the ESC so as to have a tilt with respect to the top surface of the ESC; and
direct current (DC) power or radio frequency (RF) power is supplied to the at least one second electrode independently from the first electrode.

17.-18. (canceled)

19. An apparatus for plasma processing an object, the apparatus comprising:
a chamber that includes an outer wall and a window, the outer wall defining a reaction space in which plasma is formed, and the window covering an upper portion of the outer wall;
a coil antenna positioned above the window, the coil antenna including an inner coil, an outer coil, and an additional coil; and
an electrostatic chuck (ESC) positioned in a lower portion of the chamber,
wherein:
the object to be processed is supportable on a top surface of the ESC and an electrode is located inside the ESC, and
the window includes a groove at an edge of a top surface thereof, the additional coil being in the groove.

20. The apparatus as claimed in claim 19, wherein the additional coil is configured to move up and down within the groove.

21. The apparatus as claimed in claim 19, wherein:
the inner coil is positioned above a central portion of the window,
the outer coil is positioned above an edge portion of the window, and
the additional coil is in a position further away from a center of the window than the outer coil or in a position that is a same distance from the center as that of the outer coil.

22. The apparatus of claim 19, wherein:
the electrode includes a first electrode for holding the object and at least one second electrode,
the first electrode is provided in an internal central portion of the ESC so as to be parallel with the top surface of the ESC,
the at least one second electrode is provided at an edge of the inside of the ESC so as to have a tilt with respect to the top surface of the ESC; and
direct current (DC) power or radio frequency (RF) power is supplied to the at least one second electrode independently from the first electrode.

23.-24. (canceled)
